(19) United States
(12) Patent Application Publication
(10) Pub. No.: US 2006/0120181 A1
(43) Pub. Date: Jun. 8, 2006

(54) Fault detection and isolation with analysis of built-in-test results

(75) Inventors: Richard Berbaum, Maine, NY (US); Edward R. Bestle, Owego, NY (US)

Correspondence Address: MILES & STOCKBRIDGE PC, 1751 PINNACLE DRIVE, SUITE 500, MCLEAN, VA, 22102-3833, US

(73) Assignee: Lockheed Martin Corp.

(21) Appl. No.: 11/241,937

(22) Filed: Oct. 4, 2005

Related U.S. Application Data
(63) Continuation-in-part of application No. 11/019,295, filed on Dec. 23, 2004.
(63) Continuation-in-part of application No. 10/957,608, filed on Oct. 5, 2004.
(63) Continuation-in-part of application No. 10/998,802, filed on Nov. 30, 2004.
(63) Continuation-in-part of application No. 10/998,831, filed on Nov. 30, 2004.
(60) Provisional application No. 60/615,952, filed on Oct. 6, 2004.
(60) Provisional application No. 60/616,221, filed on Oct. 7, 2004.

(51) Int. Cl. G11C 7/00

(52) U.S. Cl. 365/191

(57) ABSTRACT

A method for detecting and isolating faults in a complex system using a meta-analysis of subsystem built-in-test (BIT) results is disclosed. Subsystem BIT results may be combined with each other and with a representation of the complex system architecture and operational characteristics. A meta-analysis of the BIT results of individual modules, for example, commercial-off-the-shelf modules, may provide a diagnostic capability of a higher scope than individual subsystem BIT.

This application claims the benefit under 35 U.S.C. § 119(e) to U.S. Provisional Application No. 60/615,952, filed Oct. 6, 2004, entitled “Reasonableness Testing And Bus Diagnostics,” which is incorporated herein by reference in its entirety and to U.S. Provisional Application No. 60/616,221, filed Oct. 7, 2004, entitled “Reasonableness Testing And Bus Diagnostics,” which is incorporated herein by reference in its entirety; and also claims priority to U.S. patent application Ser. No. 11/019,295, entitled “Interactive Electronic Technical Manual System Integrated With The System Under Test”, and filed Dec. 23, 2004, which is incorporated herein by reference in its entirety; U.S. patent application Ser. No. 10/957,608, entitled “Graphical Authoring And Editing Of Mark-Up Language Sequences”, and filed Jan. 7, 2005, which is incorporated herein by reference in its entirety; U.S. patent application Ser. No. 10/998,802, entitled “Diagnostic Fault Detection And Isolation”, and filed Nov. 30, 2004, which is incorporated herein by reference in its entirety; and U.S. patent application Ser. No. 10/998,831, entitled “Enhanced Diagnostic Fault Detection And Isolation”, and filed Nov. 30, 2004, which is incorporated herein by reference in its entirety.

The present invention relates generally to diagnostic testing, and more particularly to fault detection and isolation in complex systems.

A complex system, as used herein, refers to a system having a plurality of constituent subsystems, components, or modules. Examples of complex systems include vehicles, aircraft, electronics, industrial machinery, or the like. For example, in a system comprised of commercial-off-the-shelf (COTS) modules, each module may have a built-in-test (BIT) capability. The BIT capability of the COTS modules may be limited to testing internal aspects of the COTS modules and may not provide a full test of the complex system as a whole. A need may exist to diagnose complex systems at a higher, system level. In an exemplary embodiment, the present invention provides a method for meta-analysis of COTS module BIT results. For example, the COTS module BIT results may be combined with other module BIT results and/or representations of architecture and operational knowledge of the complex system for a “meta-analysis” that may provide a test capability that is more comprehensive and better able to perform fault detection and isolation than the test capability provided by merely analyzing individual module BIT results.

### BRIEF DESCRIPTION OF THE DRAWINGS

The present invention will be described with reference to the accompanying drawings, wherein:

FIG. 1 is a high-level block diagram of an exemplary embodiment of the present invention;

FIG. 1A is a diagram of an exemplary system under test;

FIG. 2 is a diagram of an exemplary system under test;

FIG. 3 is a diagram of an exemplary diagnostic test flow of the system of FIG. 2 generated in accordance with an exemplary embodiment of the present invention;

FIG. 4 is a continuation of the exemplary diagnostic test flow of FIG. 3;

FIG. 5 is a continuation of the exemplary diagnostic test flow of FIG. 4; and

FIG. 6 is a flowchart of an exemplary method of fault detection and isolation in accordance with the present invention.

### DETAILED DESCRIPTION

The method and system for fault detection and isolation with meta-analysis of built-in-test results of the present invention is illustrated and described below with reference to the application of diagnosing military aircraft and, in particular, helicopters. It should be appreciated that the method and system of the present invention may be used in other ways and to diagnose other systems. This invention is an improvement upon the inventions described above.

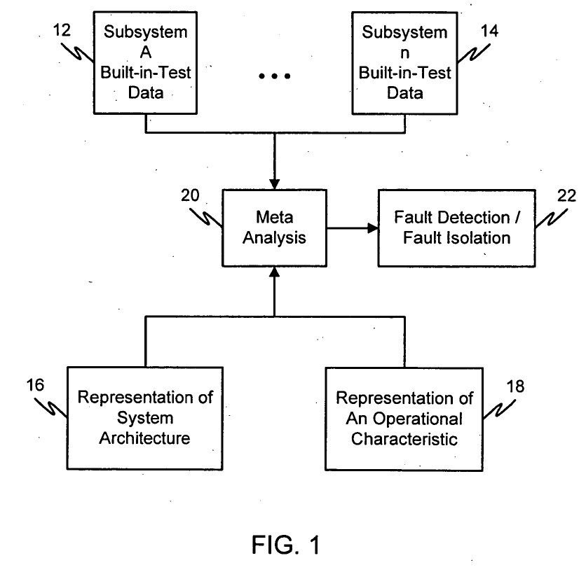

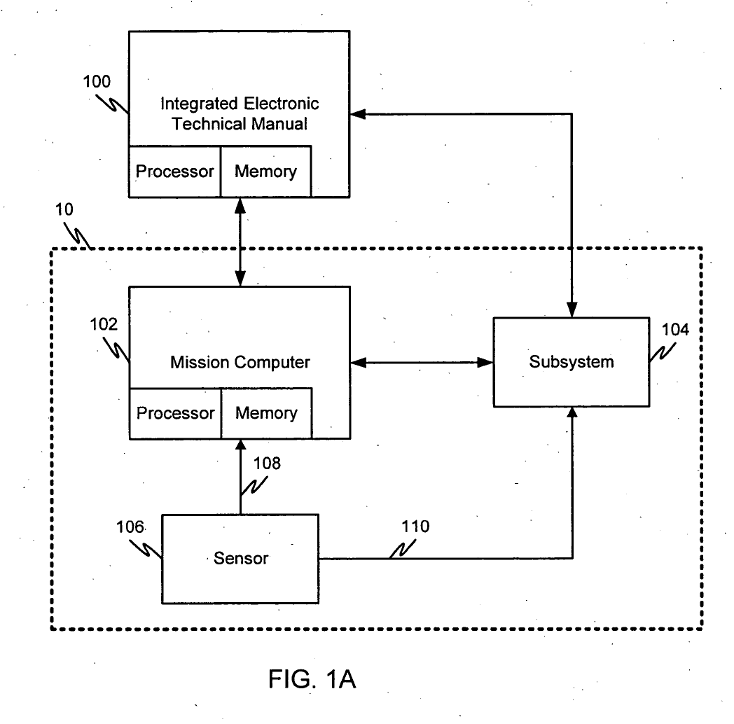

FIG. 1 is a high-level block diagram of an exemplary embodiment of the present invention. In particular, a meta-analysis module 20 receives the following as input: built-in-test results from subsystems (12 and 14), a representation of a portion of the system architecture 16, and an operational characteristic of the system or subsystem 18. The meta-analysis module 20 generates system fault detection and fault isolation information as output.

FIG. 1A is a diagram of an exemplary system under test. In particular, a system under test 10 comprises a mission computer 102, a subsystem 104, and a sensor 106. The mission computer 102 comprises a processor and a memory. An integrated electronic technical manual 100 is coupled to the mission computer 102 and the subsystem 104. The integrated electronic technical manual 100 comprises a processor and memory. The integrated electronic technical manual 100 may be coupled directly or indirectly to the subsystem 104 and mission computer 102, for example, the integrated electronic technical manual 100 may be coupled to a bus that is also coupled to the subsystem 104 and mission computer 102. Alternatively, the paths coupling the integrated electronic technical manual 100 to the subsystem 104 and mission computer 102 may be separate. In yet another embodiment, the integrated electronic technical manual 100 may be coupled to the subsystem 104 through the mission computer 102. It should be appreciated that FIG. 1 is a simplistic system having only one subsystem and is shown for illustration purposes. It should be appreciate that the system and method of the present invention may be used on systems of varying complexity.

Generally, in operation, the integrated electronic technical manual 100 contains an implementation of the fault detection and isolation with meta-analysis of built-in-test results method of the present invention. For example, the following scenario shows how the present invention may be used for fault detection and isolation, the integrated electronic technical manual 100 may interrogate the mission computer 102 in order to obtain built-in-test information from the mission computer 102. Within the built-in-test information, the mission computer may indicate a fault with the subsystem 104. The implementation of the present invention within the integrated electronic technical manual 100 includes a representation of the system architecture and operational characteristics of the system.

System architecture information includes configuration information, such as the location and interconnection of subsystems and /or components by cabling, connections, splices, buses, interfaces, and/or the like. The system architecture information can be any information related to the system, or subsystem, architecture that may permit fault detection and isolation. Operational characteristics include representations of knowledge about the system and what results of built-in-test or other tests would be expected, or “reasonable” within a certain context. It should be appreciated that specific representations of architecture knowledge or operational characteristics may vary from system to system based on the contemplated use of the invention. Further, architecture knowledge and operational characteristics may be used in combination or individually in order to achieve the desired result. By including representations of the system architecture and operational characteristics in a fault detection and fault isolation (FD/FI) system, the FD/FI capabilities may be enhanced and allow for more rapid and/or more thorough FD/FI. Further, built-in-test results from multiple subsystems or components may be compared with one another by the FD/FI method of the present invention. The FD/FI method of the present invention, as generally described above, is referred to herein as “meta-analysis” of built-in-test results.

Meta-analysis of built-in-test results of subsystems, or components, includes combining built-in-test results of individual subsystems or components for analysis, analyzing built-in-test results in light of system architecture information, analyzing built-in-test results in light of operational characteristics of a subsystem or the system as a whole, or using any combination of the above.

Because of the fault indicated by the mission computer 102, the integrated electronic technical manual 100, through the method of the present invention, may determine that a direct interrogation of the subsystem may serve to further detect and isolate the fault. The integrated electronic technical manual 100 interrogates the subsystem 104 directly to obtain built-in-test information provided by the subsystem 104.

For example, the built-in-test information provided by the subsystem 104 indicates that the sensor 106 is in an “on” state. The subsystem 104 is coupled to the sensor 106 via a connection 110. Based on this BIT result, and the representation of the system architecture indicating that a connection 108 exists between the mission computer 102 and the sensor 106, the integrated electronic technical manual 100 then interrogates the mission computer for a secondary reading of the sensor 106. The mission computer 102 indicates that the sensor 106 is in an “Off” state. By utilizing-representation of operational characteristics, in the form of, for example, logic, the present invention, through the integrated electronic technical manual 100, is able to determine that the correct indication, within context, is the “on” state and that the mission computer's indication of “off” is a fault. Through a representation of the knowledge of the system architecture, the fault can be isolated to the cabling or connections between the mission computer 102 and the sensor 106.

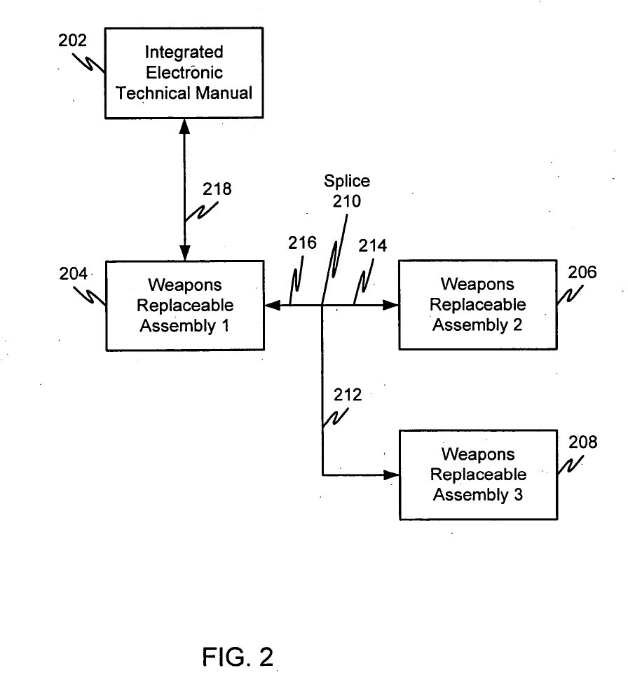

FIG. 2 is a diagram of an exemplary system under test. In particular, an integrated electronic technical manual (IETM) 202 is coupled to Weapons Replaceable Assembly 1 (WRA1) 204 by a link 218. WRA1 is coupled to Weapons Replaceable Assembly 2 (WRA2) 206 by a link 216 connecting to another link 214 through a splice 210, and to Weapons Replaceable Assembly 3 (WRA3) 208 by the link 206 connecting to another link 212 through a splice 210.

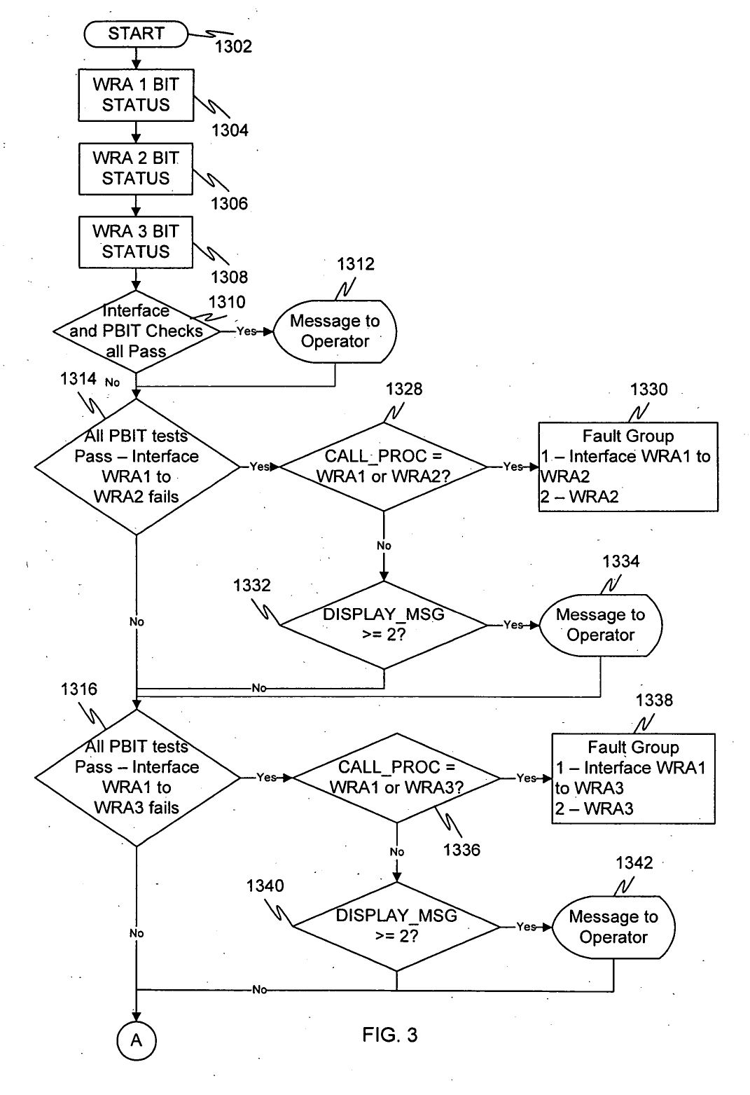

FIG. 3 is a flowchart of an exemplary diagnostic test flow sequence for the system shown in FIG. 2. In particular, control begins at step 1302 and continues to step 1304. In step 1304, PBIT is executed on WRA 1. Control then continues to step 1306. In step 1306, PBIT is executed on WRA 2. Control then continues to step 1308. In step 1308, PBIT is executed on WRA 3. Control then continues to step 1310.

In step 1310, the PBIT results and interface test results for WRA 1, WRA 2 and WRA 3 are evaluated. If the interface test and PBIT tests all pass, then control continues to step 1312, where a message is displayed to the operator that the WRA 1 interface to WRA 2 and WRA 3 passed interface test and PBIT tests. Control then continues to step 1314.

In step 1314, if the PBIT tests passed, but the interface form WRA 1 to WRA 2 fails, the control continues to step 1328, otherwise, control continues to step 1316.

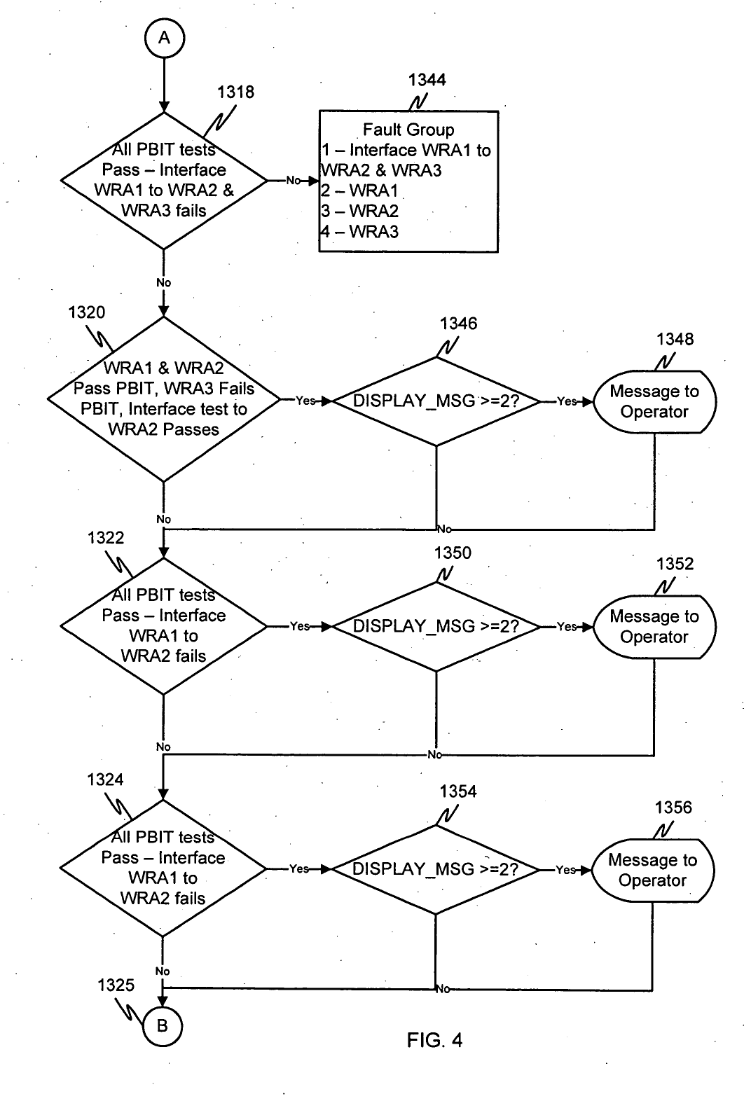

In step 1316, if the PBIT tests pass, but the interface from WRA 1 to WRA 3 fails, control continues to step 1336, otherwise control continues to step 1318 shown in FIG. 4.

In step 1318, if the PBIT tests passed, but the interface from WRA1 to WRA2 and WRA3 fails, control continues to step 1344, otherwise, control continues to step 1320.

In step 1320, if WRA 1 and WRA 2 pass PBIT, but WRA 3 fails PBIT and the interface from WRA 1 to WRA 2 passes, control continues to step 1346, otherwise, control continues to step 1322.

In step 1322, if WRA 1 and WRA 2 pass PBIT, but WRA 3 fails PBIT and the interface form WRA 1 to WRA 2 fails, then control continues to step 1350, otherwise, control continues to step 1324.

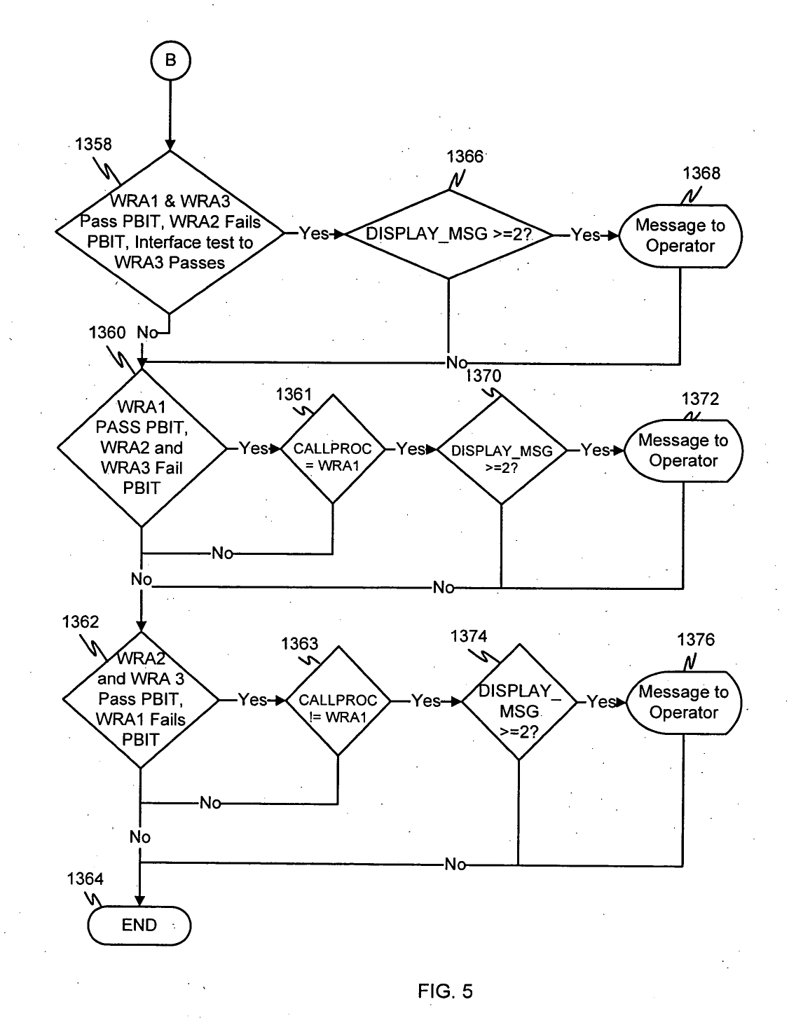

In step 1324, if WRA 1 and WRA 3 pass PBIT, but WRA 2 fails PBIT and the interface from WRA 1 to WRA 3 passes, control continues to step 1354, otherwise, control continues to step 1325, where the control sequence continues to the flowchart shown in FIG. 5.

In step 1328, the CALL_PROC variable is evaluated. If CALL_PROC is equal to WRA 1 or WRA 2, control continues to step 1330, otherwise, control continues to step 1332. In step 1330, the fault group for the interface from WRA 1 to WRA 2 and for WRA 2 is displayed. Since the interface to WRA 3 passed, the fault may be isolated to the interface between the splice (where the interface in FIG. 2 splits from WRA 1 and connects to WRA 2 and WRA 3) and WRA 2 or to WRA 2 itself Control then ends for this test sequence.

In step 1332, the DISPLAY_MSG variable is evaluated. If DISPLAY_MSG is greater than or equal to two, then a message is displayed to the operator, such as, for example, “WRA 1 interface to WRA 3 passed. Interface to WRA 2 failed. Probable cause is interface wiring between the splice and WRA 2. Run WRA 2 diagnostics to isolate.” Control continues to step 1316.

In step 1336, the CALL_PROC variable is evaluated. If CALL_PROC is equal to WRA 1 or WRA 3, control continues to step 1338. Otherwise, control continues to step 1340. In step 1338, a fault group is displayed comprising the interface from WRA 1 to WRA 3 and WRA 3. Since the interface to WRA 2 passed, the fault may be isolated to the interface between the splice and WRA 3 or to WRA 3 itself. Control ends for this test sequence.

In step 1340, the DISPLAY_MSG variable is evaluated. If DISPLAY_MSG is greater than or equal to two, then control continues to step 1342. Otherwise, control continues to step 1318 (shown in FIG. 4).

In step 1342, a message is displayed to the operator, such as, for example, “WRA 1 interface to WRA 2 passed. Interface to WRA 3 failed. Probable cause is interface wiring between the splice and WRA 3. Run WRA 3 diagnostics to isolate.” Control continues to step 1318 (shown in FIG. 4).

The A sheet connector designates a connection onto the A designator of FIG. 4 for continuation of diagram shown in FIG. 3. FIG. 4 shows a continuation of the exemplary diagnostic test flow of FIG. 3.

In step 1344, a fault group is displayed containing the interface from WRA 1 to WRA 2 and WRA 3, WRA 1, WRA 2 and WRA 3. Control then ends for this test sequence.

In step 1346, the DISPLAY_MSG variable is evaluated. If DSIPLAY_MSG is greater than for equal to two, then control continues to step 1348. Otherwise, control continues to step 1322.

In step 1348, a message is displayed to the operator, such as, for example, “WRA 1 interface to WRA 2 passed. Interface test to WRA 3 cannot be validated. WRA 3 did not pass critical BIT checks. Run WRA 3 to isolate.” Control continues to step 1322

In step 1350, the DISPLAY_MSG variable is evaluated. If DISPLAY_MSG is greater than or equal to two, then control continues to step 1352. Otherwise, control continues to step 1324.

In step 1352, a message is displayed to the operator, such as, for example, “WRA 1 interface to WRA 2 failed. Interface test to WRA 3 cannot be validated, WRA 3 did not pass critical BIT checks. Run WRA 3 diagnostics to isolate.” Control continues to step 1324.

In step 1354, the DISPLAY_MSG variable is evaluated. If DISPLAY_MSG is greater than or equal to two, control continues to step 1356. Otherwise, control continues to step 1325 where the control sequence continues to the flowchart shown in FIG. 5.

In step 1356, a message is displayed to the operator, such as, for example, “WRA 1 interface to WRA 3 passed. Interface test to WRA 2 cannot be validated, WRA 2 did not pass critical BIT checks. Run WRA 2 diagnostics to isolate.” Control continues to step 1325, where the control sequence continues to the flowchart shown in FIG. 5.

In FIG. 5, the flowchart shows the continuation of the control sequence, which began in FIG. 3 and continued to FIG. 4. In particular, in step 1358, if WRA 1 and WRA 3 pass PBIT, but WRA 2 fails PBIT and the interface from WRA 1 to WRA 3 passes, control continues to step 1366, otherwise, control continues to step 1360.

In step 1360, if WRA 1 passes PBIT, but WRA 2 and WRA 3 fail PBIT and the interface form WRA 1 to WRA 3 fails, then control continues to step 1361, otherwise, control continues to step 1362.

In step 1362, if WRA 2 and WRA 3 pass PBIT, but WRA 1 fails PBIT, control continues to step 1363, otherwise, control continues to step 1364, where the control sequence ends.

In step 1366, the DISPLAY_MSG variable is evaluated. If DSIPLAY_MSG is greater than for equal to two, then control continues to step 1368. Otherwise, control continues to step 1360.

In step 1368, a message is displayed to the operator, such as, for example, “WRA 1 interface to WRA3 FAILED. Interface test to WRA2 cannot be validated, WRA2 did not pass critical BIT checks. Run WRA2 diagnostics to isolate.” Control continues to step 1360.

In step 1361, the CALLPROC variable is tested. If the CALLPOC variable equals WRA1 then conrol continues to step 1370, otherwise control continues to step 1362. In step 1370, the DISPLAY_MSG variable is evaluated. If DISPLAY_MSG is greater than or equal to two, then control continues to step 1372. Otherwise, control continues to step 1362.

In step 1372, a message is displayed to the operator, such as, for example, “Interface test to WRA2 cannot be validated, WRA2 did not pass critical BIT checks. Run WRA2 diagnostics to isolate. Interface test to WRA3 cannot be validated, WRA3 did not pass critical BIT checks. Run WRA3 diagnostics to isolate.” Control continues to step 1362.

In step 1363, the CALLPROC variable is evaluated. If the CALLPROC variable is not equal to WRA1, then control continues to step 1374, otherwise control continues to step 1364. In step 1374, the DISPLAY_MSG variable is evaluated. If DISPLAY_MSG is greater than or equal to two, control continues to step 1376. Otherwise, control continues to step 1364 where the control sequence ends.

In step 1376, a message is displayed to the operator, such as, for example, “Interface test to WRA1 cannot be validated, WRA1 did not pass critical BIT checks. Run WRA1 diagnostics to isolate.” Control continues to step 1364, where the control sequence ends.

Although the method and system for fault detection and isolation with meta-analysis of built-in-test results of the present invention have been described and illustrated in conjunction with the troubleshooting of a military aircraft, the system and method can be configured to troubleshoot any system having any number of interconnected components, such as the complex systems created by the aerospace, automotive, marine, electronics, power generation and computer industries. As such, the foregoing description of the utilization of the method and system for fault detection and isolation with meta-analysis of built-in-test results in the military aircraft industry was for purposes of illustration and example, and not of limitation because the method and system for fault detection and isolation with meta-analysis of built-in-test results described above is applicable to other systems built by various industries.

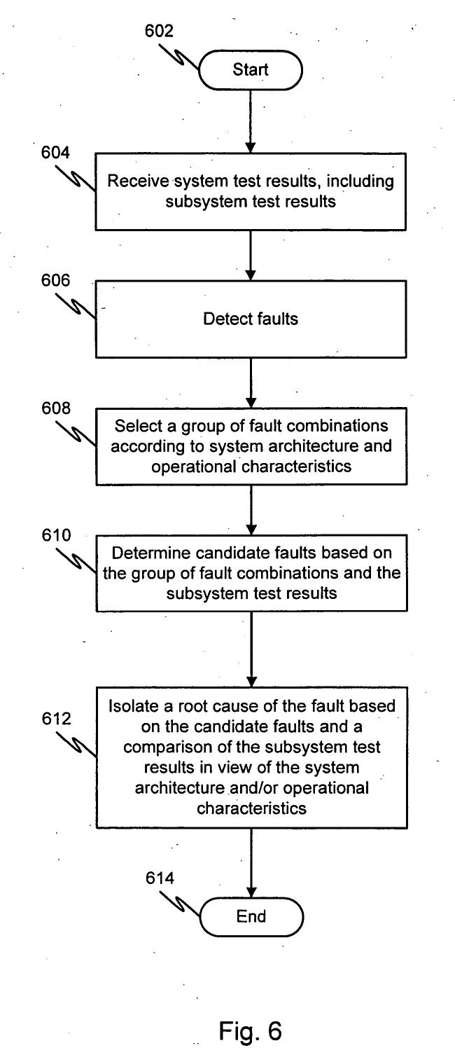

FIG. 6 is a flowchart of an exemplary method of fault detection and isolation in accordance with the present invention. In particular, the control sequence begins at step 602 and continues to step 604.

In step 604, the fault detection and-isolation system with analysis of built-in-test results receives system test results including subsystem test results. Subsystem test results may include built-in-tests (BIT) such as initial BIT, periodic BIT, initiated BIT, and/or the like. The subsystem test results may also include results of any tests, including those tests requested by operators, recorded during operation, initiated by technicians, and/or the like.

The system test results may include built-in-test results from one or more subsystems, the subsystems may be redundant backups of each other, or may be different systems. The built-in-test results from the subsystems may be communicated in protocols that are the same, in protocols that are different but compatible, or in protocols that are different and are not designed for compatibility with each other. The fault detection and isolation system with analysis of built-in-test results may serve as an overall system built-in-test which incorporates the heterogeneous built-in-tests of one or more of the subsystems, or weapons replaceable assemblies, of a complex system. The reasonableness testing, or meta-analysis, of the subsystem test results is a higher-level test that may incorporate complex system architecture or operational characteristic information coded into logic operations for processing by a computer or data processor. Control then continues to step 606.

In step 606, the fault detection and isolation system with meta-analysis of built-in-test results detects a fault (if any faults are present) from among the system and/or subsystem test results. Control then continues to step 608.

In step 608, a group of potential fault combinations are selected based on the system architecture or operational characteristic of the system or subsystem. Control then continues to step 610.

In step 610, a group of candidate faults is determined based on the group of potential fault combinations and the test results. Control then continues to step 612.

In step 612, a root cause (or causes) of the fault is isolated from among the group of candidate faults by performing a meta-analysis of the test results in light of the representation of system architecture and operational characteristics. In this step, the representations of the system architecture and/or operational characteristics are used to compare the “reasonableness” of the test results. Based on this comparison, and using the representation of the system architecture and operational characteristics, a fault in the system may be detected and isolated. Control continues to step 614, where the control sequence ends.

The method and system for fault detection and isolation with meta-analysis of built-in-test results, as shown in the above figures, may be implemented on a general-purpose computer, a special-purpose computer, a programmed microprocessor or microcontroller and peripheral integrated circuit element, an ASIC or other integrated circuit, a digital signal processor, a hardwired electronic or logic circuit such as a discrete element circuit, a programmed logic device such as a PLD, PLA, FPGA, PAL, or the like. In general, any process capable of implementing the functions described herein can be used to implement fault detection and isolation with meta-analysis of built-in-test results according to this invention.

Furthermore, the disclosed method and system of fault detection and isolation with meta-analysis of built-in-test results may be readily implemented in software using object or object-oriented software development environments that provide portable source code that can be used on a variety of computer platforms. Alternatively, the disclosed method of fault detection and isolation with meta-analysis of built-in-test results may be implemented partially or fully in hardware using standard logic circuits or a VLSI design. Other hardware or software can be used to implement the systems in accordance with this invention depending on the speed and/or efficiency requirements of the systems, the particular function, and/or a particular software or hardware system, microprocessor, or microcomputer system being utilized. The electronic communication control device illustrated herein can readily be implemented in hardware and/or software using any known or later developed systems or structures, devices and/or software by those of ordinary skill in the applicable art from the functional description provided herein and with knowledge of the computer and electronic test arts.

Moreover, the disclosed method and system for fault detection and isolation with meta-analysis of built-in-test results may be readily implemented in software executed on programmed general-purpose computer, a special purpose computer, a microprocessor, or the like. In these instances, the fault detection and isolation with meta-analysis of built-in-test results of this invention can be implemented as a program embedded on a personal computer such as a JAVA® or CGI script, as a resource residing on a server or graphics workstation, as a routine embedded in a dedicated encoding/decoding system, or the like. The system can also be implemented by physically incorporating the method or system for fault detection and isolation with meta-analysis of built-in-test results into a software and/or hardware system, such as the hardware and software systems of an interactive electronic technical manual.

It is, therefore, apparent that there is provided in accordance with the present invention, a system and method for fault detection and isolation with meta-analysis of built-in-test results. While this invention has been described in conjunction with a number of embodiments, it is evident that many alternatives, modifications and variations would be or are apparent to those of ordinary skill in the applicable arts. Accordingly, applicants intend to embrace all such alternatives, modifications, equivalents and variations that are within the spirit and scope of this invention.

What is claimed is:

1. A computer system for detecting and isolating a fault in a helicopter using an analysis of subsystem test results, said computer system comprising:
a processor; and
a memory including software instructions adapted to cause the computer system to perform the steps of:
receiving a helicopter test result including a first subsystem test result from a first built-in-test in a first weapons replaceable assembly and a second subsystem test result from a-second built-in-test in a second weapons replaceable assembly, wherein the first weapons replaceable assembly is different from the second weapons replaceable assembly;
detecting the fault in the helicopter based on the helicopter test result;
selecting a group of fault combinations based on a system architecture of the helicopter and a representation of an operational characteristic of the helicopter;
evaluating the first subsystem test result and the second subsystem test result at a system level based on the group of fault combinations to determine candidate faults; and
isolating a root cause of the fault from among the candidate faults by performing a reasonableness analysis of the helicopter test result including cross referencing related tests and comparing the first subsystem test result and the second subsystem test result, wherein related tests are predetermined based on the system architecture of the helicopter and the operational characteristic of the helicopter, and
wherein the computer system forms a portion of an integrated electronic technical manual.

2. The computer system of claim 1, wherein the first and second subsystem test results are compared in order to validate interface operation and check data transfer status.

3. The computer system of claim 1, wherein the processor and memory are distributed between the integrated electronic technical manual and the helicopter such that the integrated electronic technical manual and the helicopter each execute a portion of the software instructions.

4. A computer program product for enabling a computer to detect and isolate a fault in an aircraft using a meta-analysis of built-in-test results, said computer program product comprising:
software instructions for enabling the computer to perform predetermined operations; and
a computer readable medium bearing the software instructions;
the predetermined operations including the steps of:
receiving an aircraft test result including a first subsystem test result and a second subsystem test result;
detecting the fault in the aircraft based on the aircraft test result;
selecting a group of fault combinations based on an architecture of the aircraft subsystems and a representation of an operational characteristic of the aircraft;
evaluating the first subsystem test result and the second subsystem test result at a system level based on the group of fault combinations to determine candidate faults; and
isolating a root cause of the fault in the aircraft at a system level.

5. The computer program product of claim 4, wherein the step of isolating a root cause of the fault in the aircraft at a system level comprises performing a meta-analysis of the aircraft test result.

6. The computer program product of claim 5, wherein the meta-analysis of the aircraft test result includes cross-referencing selected subsystem tests.

7. The computer program product of claim 6, wherein the meta-analysis of the aircraft test result includes comparing the first subsystem test result and the second subsystem test result.

8. The computer program product of claim 5, wherein the selected subsystem tests are determined based on the system architecture of the aircraft and the operational characteristic of the aircraft.

9. The computer program product of claim 4, wherein the aircraft is a helicopter.

10. The computer program product of claim 4, wherein the computer is included in an integrated electronic technical manual.

11. A method for detecting and isolating a fault in a complex system, said method comprising:
providing a complex system test result including a first subsystem test result and a second subsystem test result;
detecting the fault in the complex system based on the complex system test result; and
isolating a root cause of the fault through a meta-analysis of the first subsystem test results and the second subsystem test result; wherein the first subsystem test result is from a first built-in-test and the second subsystem test result is from a second built-in-test different from the first built-in-test, and wherein the first subsystem test result is communicated in a first protocol and the second subsystem test result is communicated in a second protocol not designed for compatibility with the first protocol.

12. The method of claim 11, wherein the meta-analysis includes cross referencing related tests.

13. The method of claim 11, wherein the meta-analysis includes comparing the first subsystem test result and the second subsystem test result.

14. The method of claim 11, wherein the meta-analysis includes validating interface operation and checking data transfer status.

15. The method of 12, wherein related tests are selected based on a system architecture of the complex system and operational characteristics of the complex system.

16. The method of claim 11, wherein the meta-analysis includes combining the first subsystem test result and the second subsystem test result.

17. The method of claim 11, wherein the meta-analysis includes combining the complex system test result with a representation of the complex system architecture.

18. The method of claim 11, wherein the meta-analysis includes combining the complex system test result with an operational characteristic of the complex system.

19. The method of claim 11, wherein the complex system is an aircraft.

20. The method of claim 11, wherein the complex system is a helicopter.
